(19) United States
(12) Patent Application Publication
(10) Pub. No.: US 2014/0352607 A1
(43) Pub. Date: Dec. 4, 2014

(54) Raw Material for Growth of Ingot, Method for Fabricating Raw Material for Growth of Ingot and Method for Fabricating Ingot

(71) Applicants: Bum Sup Kim, Seoul (KR); Kyoung Seok Min, Seoul (KR)

(72) Inventors: Bum Sup Kim, Seoul (KR); Kyoung Seok Min, Seoul (KR)

(73) Assignee: LG INNOTEK CO., LTD., Seoul (KR)

(21) Appl. No.: 14/235,708

(22) PCT Filed: Jul. 26, 2012
(86) PCT No.: PCT/KR2012/005966

§ 371 Date: Jul. 1, 2014

(30) Foreign Application Priority Data
Jul. 28, 2011 (KR) 10-2011-0075467

(51) Int. Cl. C01B 31/36; C30B 29/36; C30B 23/02

(52) U.S. Cl. CPC C01B 31/36; C30B 23/02; C30B 29/36
USPC 117/84; 428/402; 423/345; 264/5

(57) ABSTRACT

A raw material for growing an ingot according to the embodiment comprises an agglomerate raw material in which fine particles are agglomerated, wherein the agglomerate raw material has a granular shape. A method for fabricating a raw material for growing an ingot according to the embodiment comprises the steps of: preparing an ultrahigh-purity powder; and granulating the ultrahigh-purity powder. A method for fabricating an ingot according to the embodiment comprises the steps of: preparing a raw material; filling the raw material in a crucible; and growing a single crystal from the raw material, wherein the raw material comprises an agglomerate raw material in which fine particles are agglomerated, and the agglomerate raw material has a granular shape.

### TECHNICAL FIELD

The disclosure relates to a raw material for growth of an ingot, a method for fabricating the raw material for growth of the ingot, and a method for fabricating the ingot.

### BACKGROUND ART

In general, materials are very important factors to determine the property and the performance of final products in the electric, electronic and mechanical industrial fields

SiC represents the superior thermal stability and superior oxidation-resistance property. In addition, the SiC has the superior thermal conductivity of about 4.6 W/Cm° C., so the SiC can be used for fabricating a large-size substrate having a diameter of about 2 inches or above. In particular, the single crystal growth technology for the SiC is very stable actually, so the SiC has been extensively used in the industrial field as a material for a substrate.

In order to grow the single crystal for SiC, a seeded growth sublimation scheme has been suggested. In this case, after putting a raw material in a crucible, an SiC single crystal serving as a seed is provided on the raw material. A temperature gradient is formed between the raw material and the seed, so that the raw material in the crucible is dispersed to the seed, and re-crystallized to grow a single crystal.

SiC powder is typically used as a raw material to grow the SiC single crystal. When growing the single crystal having high quality, it is advantageous if the SiC powder has higher purity. However, although it is possible to fabricate high-purity fine SiC powder, a method for fabricating granular SiC powder having high purity is under development. Thus, when the high-purity fine SiC powder is filled into a crucible, the high-purity fine SiC powder may not be easily filled and particles may be caused, exerting an influence upon the quality of the single crystal.

### DISCLOSURE OF INVENTION

### Technical Problem

The embodiment provides a raw material which can grow a high-quality ingot.

### Solution to Problem

A raw material for growing an ingot according to the embodiment comprises an agglomerate raw material in which fine particles are agglomerated, wherein the agglomerate raw material has a granular shape.

A method for fabricating a raw material for growing an ingot according to the embodiment comprises the steps of: preparing an ultrahigh-purity powder; and granulating the ultrahigh-purity powder.

A method for fabricating an ingot according to the embodiment comprises the steps of: preparing a raw material; filling the raw material in a crucible; and growing a single crystal from the raw material, wherein the raw material comprises an agglomerate raw material in which fine particles are agglomerated, and the agglomerate raw material has a granular shape.

### Advantageous Effects of Invention

An ultrahigh-purity raw material according to the embodiment has a granular shape, so that it is easy to fill the raw material into a crucible. The granular shape comprises a spherical shape and has a smooth surface, so that it is possible to efficiently fill the raw material under the same volume condition. Further, since particles are minimized, the product yield of ingots grown from the raw material may be increased. Further, since the raw material has ultrahigh purity, impurities may be reduced and it is possible to grow a high quality ingot.

Meanwhile, according to the method for fabricating the raw material for growing the ingot of the embodiment, the raw material having the above-mentioned effects may be simply fabricated.

According to the method for fabricating the ingot, the ingot having a high quality and a high product yield may be fabricated.

### BRIEF DESCRIPTION OF DRAWINGS

FIG. 1 is a sectional view of a raw material for growing an ingot according to the embodiment;

FIG. 2 is a view showing an application example of the raw material for growing the ingot according to the embodiment; and

FIG. 3 is a view illustrating a method for fabricating the raw material for growing the ingot according to the embodiment.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or over the other substrate, layer (or film), region, pad, or pattern, or one or more intervening layers may also be present. Such a position of the layer has been described with reference to the drawings.

Since the thickness and size of each layer shown in the drawings may be modified for the purpose of convenience or clarity of description, the size of elements does not utterly reflect an actual size.

Hereinafter, the embodiment will be described with reference to accompanying drawings.

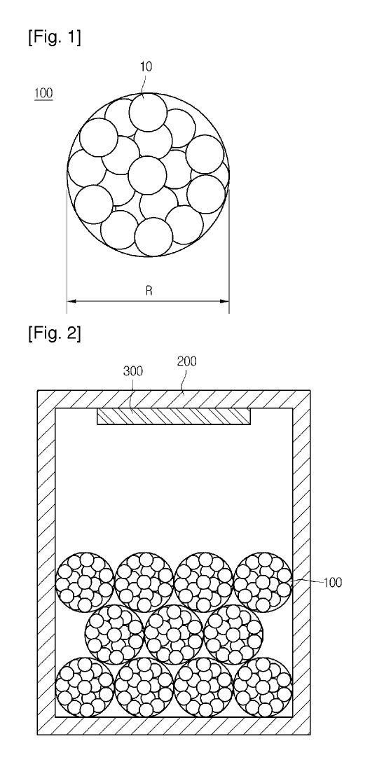

A raw material for growing an ingot according to the embodiment will be described in detail with reference to FIGS. 1 and 2. FIG. 1 is a sectional view of the raw material for growing the ingot according to the embodiment. FIG. 2 is a view showing the application example of the raw material for growing the ingot according to the embodiment.

Referring to FIG. 1, the raw material for growing the ingot comprises fine particles 10. The fine particles 10 may comprise silicon carbide (SiC) powder. The silicon carbide powder may have purity of 99.9% or above. In detail, the purity of the silicon carbide powder may be in the range of 99.9% to 99.9999999%.

The fine particles 10 may exist in an agglomerated state. That is, the raw material for growing the ingot according to the embodiment may comprise an agglomerate raw material 100 in which the fine particles 10 are agglomerated.

The agglomerate raw material 100 may have a granular shape which is formed by agglomerating the fine particles 10. The agglomerate raw material 100 may has a spherical shape. The diameter R of the agglomerate raw material 100 may be in a range of 100 μm to 1000 μm.

The agglomerate raw material 100 may be used as a raw material to grow the ingot. In detail, referring to FIG. 2, the plurality of the agglomerate raw materials 100 are filled in the crucible 200, and if the temperature of the crucible 200 is increased to the ingot growth temperature, the agglomerate raw material 100 is sublimated such that the agglomerate raw material 100 is transferred to a seed 300. The ingot may be grown from the seed 300. When the ingot is grown, the purity of the raw material may exert a great influence on the quality of the ingot grown from the crucible 200. When a high-purity raw material is used, impurities introduced into the ingot grown from the high-purity raw material may be diminished, so that defect may not occur.

However, since such a high-purity raw material mainly exists in a fine particle state, when the high-purity raw material is filled in the crucible 200, a particle problem may be caused. Further, since the fine powder has high frictional force and electrostatic force, the fine powder may not be easily filled and filling density may become lower.

The ultrahigh-purity raw material according to the embodiment is an agglomerate raw material 100 and has the granular shape, so that the ultrahigh-purity raw material may be easily filled in the crucible 200. The granular shape comprises a spherical shape and has a smooth surface, so that it is possible to efficiently fill the raw material under the same volume condition. Further, since particles are reduced, a product yield of ingots grown from the raw material may be improved. Further, as described above, since the raw material has ultrahigh-purity, impurities may be reduced and a high-quality ingot can be grown.

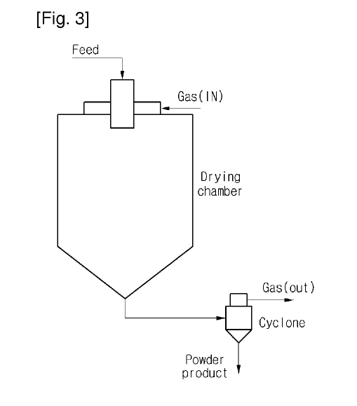

Hereinafter, the method for fabricating the raw material for growing the ingot according to the embodiment will be described with reference to FIG. 3. In the following description, for the purpose of clear and simple explanation, the details of structures and components the same as those in the above description or extremely similar to those in the above description will be omitted.

FIG. 3 is a view illustrating the method for fabricating the raw material for growing the ingot according to the embodiment.

The method for fabricating the raw material for growing the ingot according to the embodiment comprises the steps of preparing an ultrahigh-purity powder, and granulating the ultrahigh-purity powder.

The ultrahigh-purity powder may be fine particles.

In the step of preparing the ultrahigh-purity powder, ultrahigh-purity silicon carbide powder may be prepared.

The purity of the ultrahigh-purity powder may be 99.9% or above. In detail, the purity of the SiC powder may be in the range of 99.9% to 99.9999999%.

A scheme for obtaining the silicon carbide powder comprises a carbon-thermal reduction scheme, a direct reaction scheme, a liquid polymer thermal decomposition scheme, and a high-temperature self-propagating combustion synthesis scheme.

According to the above technologies, the silicon carbide is manufactured by mixing a solid-phase silicon source, such as SiO2 or Si, with a carbon source, such as carbon or graphite, and heat-treating the mixture at the temperature in the range of 1350° C. to 2000° C.

Specifically, among the above schemes, the carbon-thermal reduction and direct reaction schemes are typically used for obtaining high-purity silicon carbide particles.

As one example, ultrahigh-purity silicon carbide particles may be obtained through the following procedure. First, a step of forming a silicon carbide raw material mixture by mixing an SiO2 powder and a carbon source may be performed. The carbon source may be carbon black or a resin material. Further, the mixing ratio of carbon to silicon may be in the range of 1 to 3.

Then, the step of obtaining the silicon carbide particle by heat-treating the mixture material in a crucible at the temperature in the range of 1350° C. to 2000° C. for 30 minutes to 7 hours is performed. The crucible may be formed of graphite. The inner space of the crucible may be vacuum or filled with inert gas.

However, the embodiment is not limited to the above, and various methods may be used to obtain the ultrahigh-purity SiC powders.

In the granulating step, the ultrahigh-purity powder may be agglomerated and granulated. In detail, the granulating step may comprise the step of mixing the ultrahigh-purity powder with an additive and spray-drying the mixture.

The spray drying is called a process that obtains a spherical granule by spraying a liquid-phase raw material in the drying medium at the high-temperature. The raw material may be in the form of a solution or a paste. The spray drying is very simple as compared with any other drying schemes and has a benefit in terms of continuous mass production.

In the granulating step, slurry may be fabricated by adding an additive to the ultrahigh-purity powder. The additive may comprise various organic additives such as a binder, a plasticizer, a lubricant and a dispersant. Slurry having superior dispersion property and stability may be fabricated using the additive.

Referring to FIG. 3, the slurry may be supplied into a drying chamber. A particle size of the granule may vary according to the amount of slurry to be supplied. If the amount of slurry is increased, the particle size of the granule may become larger. Thus, the amount of slurry to be supplied may vary depending on the particle size of the granule to be manufactured.

The drying chamber can be kept with the high temperature, dry and hot wind atmosphere. If the slurry is spayed in the form of a liquid droplet under the hot wind atmosphere, the slurry comes into contact with cool gas at the initial stage so that moisture in the liquid droplet is reduced. Then, the slurry comes into contact with the hot wind atmosphere so that the powder comprised in the slurry may have a hard outer surface. As the powder is uniformly exposed to heat, the powder is dropped down to the bottom of the drying chamber. After the spraying and drying step is performed, the ultrahigh-purity powder may be granulated through a cyclone so that the spherical granule may be provided.

Hereinafter, a method for fabricating an ingot according to the embodiment will be described.

The method for fabricating the ingot according to the embodiment comprises the steps of preparing a raw material, filling the raw material in a crucible, and growing a single crystal from the raw material.

In the step of preparing the raw material, an agglomerate raw material in which fine particles are agglomerated may be prepared. In detail, the agglomerate raw material may have a granular shape. The raw material may comprise the raw material for growing the ingot according to the embodiment described above.

The step of preparing the raw material may comprise the steps of preparing an ultrahigh-purity powder and granulating the ultrahigh-purity powder. The step of preparing the raw material may comprise the method for fabricating the raw material for growing the ingot according to the embodiment described above.

In the step of filling the raw material in the crucible, the raw material has a granular shape, so that the raw material can be easily filled in the crucible. The granular shape comprises a spherical shape and has a smooth surface, so that it is possible to efficiently fill the raw material under the same volume condition. Further, particles may be minimized.

According to the method for fabricating the raw material of the embodiment, since the raw material has an ultrahigh-purity, a high-quality ingot may be grown and the product yield may be improved.

Any reference in this specification to “one embodiment,” “an embodiment,” “example embodiment,” etc., means that a particular feature, structure, or characteristic described in connection with the embodiment is comprised in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A raw material for growing an ingot, the raw material comprising:
an agglomerate raw material in which fine particles are agglomerated, wherein the agglomerate raw material has a granular shape.

2. The raw material of claim 1, wherein the raw material comprises a plurality of agglomerate raw materials.

3. The raw material of claim 1, wherein the agglomerate raw material has a spherical shape.

4. The raw material of claim 1, wherein the agglomerate raw material has a diameter in a range of 100 μm to 1000 μm.

5. The raw material of claim 1, wherein the fine particle comprises silicon carbide (SiC).

6. The raw material of claim 1, wherein the fine particle has purity of 99.9% or above.

7. The raw material of claim 1, wherein the fine particle has purity in a range of 99.9% to 99.9999999%.

8. A method for fabricating a raw material for growing an ingot, the method comprising:
preparing ultrahigh-purity powder; and
granulating the ultrahigh-purity powder.

9. The method of claim 8, wherein the ultrahigh-purity powder comprises a fine particle.

10. The method of claim 8, wherein the ultrahigh-purity powder has purity in a range of 99.9% to 99.9999999%.

11. The method of claim 8, wherein the ultrahigh-purity powder has purity of 99.9% or above.

12. A method of claim 8, wherein the ultrahigh-purity powder comprises silicon carbide.

13. The method of claim 8, wherein the granulating of the ultrahigh-purity powder comprises mixing the ultrahigh-purity powder with an additive and spray-drying the mixture.

14. A method for fabricating an ingot, the method comprising:
preparing a raw material;
filling the raw material in a crucible; and
growing a single crystal from the raw material,
wherein the raw material comprises an agglomerate raw material in which fine particles are agglomerated, and the agglomerate raw material has a granular shape.

15. The method of claim 14, wherein the preparing of the raw material comprises:
preparing ultrahigh-purity powder; and
granulating the ultrahigh-purity powder.

16. The method of claim 15, wherein the granulating of the ultrahigh purity powder comprises mixing the ultrahigh-purity powder with an additive and spray-drying the mixture.
